(19) United States
(12) Patent Application Publication
(10) Pub. No.: US 2026/0206492 A1
(43) Pub. Date: Jul. 16, 2026

(54) METHOD FOR PREPARING DOUBLE-LAYER HALIDE PEROVSKITE FILM USING ECO-FRIENDLY SOLVENT, PEROVSKITE FILM PREPARED THEREBY AND ENERGY HARVESTING DEVICE COMPRISING SAME

(71) Applicant: IUCF-HYU (INDUSTRY-UNIVERSITY COOPERATION FOUNDATION HANYANG UNIVERSITY), Seoul (KR)

(72) Inventors: Tae Whan KIM, Seoul (KR); Yong Hun LEE, Anyang-si Gyeonggi-do (KR); Ming Jun LI, Seoul (KR); Dae Hun KIM, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/424,821

(22) Filed: Dec. 18, 2025

Related U.S. Application Data
(63) Continuation of application No. PCT/KR2024/006720, filed on May 17, 2024.

(30) Foreign Application Priority Data
Jun. 19, 2023 (KR) 10-2023-0077885

(51) Int. Cl. H10N 30/092; H10N 30/30; H10N 30/50; H10N 30/85

(52) U.S. Cl. CPC H10N 30/092; H10N 30/30; H10N 30/50; H10N 30/852

(57) ABSTRACT

The present invention relates to a method for preparing a halide perovskite film having a double-layer structure and excellent piezoelectric performance by using an eco-friendly solvent, a perovskite film prepared by using the same, and an energy harvesting device comprising the same. In the present invention, by using lactate ester and monoterpene, which are eco-friendly solvents, as solvents of the halide perovskite precursor, the perovskite layers can be stably formed, and a perovskite film having very excellent piezoelectric performance can be prepared according to the formation of a double-layer structure of a three-dimensional perovskite and a zero-dimensional perovskite. Therefore, by using the present invention, an environmental pollution problem caused by the use of a solvent during the formation of the perovskite film can be solved, and the piezoelectric performance of the film can be greatly improved through optimization of materials and structure.

### CROSS-REFERENCE TO RELATED APPLICATIONS

This application is a Continuation of International Application No. PCT/KR2024/006720 filed on May 17, 2024, which claims priority to Korean Patent Application No. 10-2023-0077885 filed on Jun. 19, 2023, the entire contents of which are herein incorporated by reference.

### TECHNICAL FIELD

The present invention relates to a method for preparing a double-layer halide perovskite film using an eco-friendly solvent, a perovskite film prepared by using the same, and an energy harvesting device comprising the same, and more specifically, relates to a method for preparing a double-layer halide perovskite film having excellent piezoelectric performance by using an eco-friendly solvent, a perovskite film prepared by using the same, and an energy harvesting device comprising the same.

### BACKGROUND ART

An energy harvesting device is a device that converts wasted energy into electrical energy, and is a device realized by various principles such as piezoelectric, photovoltaic, and thermoelectric.

As a material exhibiting such energy conversion characteristics, a material having a perovskite structure is widely known. The perovskite refers to a material having a crystal structure formed by binding two types of cations and one type of anion, and depending on the type of anion, it can be classified into an oxide perovskite comprising an oxygen anion and a halide perovskite comprising a halogen anion.

As an example of an oxide perovskite material, lead zirconate titanate (PZT) may be mentioned. The PZT has an advantage of having a high dielectric constant and excellent piezoelectric characteristics, and thus is a material widely used in piezoelectric devices. For example, Korean Patent Publication No. 10-2016-0015805 discloses a piezoelectric device using a PZT-based piezoelectric ceramic material having an ABO₃ perovskite crystal structure. However, the PZT-based material required sintering at a high temperature of 1,200° C., and thus had poor processability, and during this process, PbO volatilized rapidly around 1,000° C., causing a problem of performance degradation. In addition, due to its inherent brittleness, it was difficult to apply it to flexible devices.

Meanwhile, halide perovskite materials have advantages in that luminous efficiency and photoelectric efficiency are excellent, manufacturing cost is low, and thin films can be manufactured by a solution process, and thus large-area production and mass production are easy. Due to such advantages, halide perovskite materials are attracting attention as next-generation promising materials applicable to various electronic devices such as display devices, solar cells, piezoelectric generators, precision measuring instruments, optical sensors, gas sensors, touch sensors, memory devices, transistors, and medical devices.

For example, as a technology related to halide perovskite materials, Korean Registered Patent Publication No. 10-2501662 describes a precursor solution comprising a halide perovskite and a functional additive. As described in the above technology, generally, a precursor solution of halide perovskite is prepared by using an aprotic solvent such as dimethylformamide (DMF), but in this case, there was a disadvantage that it is harmful to the human body and the environment due to the toxicity of the solvent, and when the solvent is replaced with a general eco-friendly solvent, there was a limitation that piezoelectric performance deteriorated. In addition, the energy conversion characteristics of halide perovskite have been mainly studied focusing on photoelectric characteristics, and research on piezoelectric characteristics is still insufficient.

Accordingly, development of a technology for forming a perovskite film capable of exhibiting excellent piezoelectric performance while enabling stable film formation by using an eco-friendly solvent is required.

### DETAILED DESCRIPTION OF THE INVENTION

### Technical Problem

The object of the present invention is to provide a method for preparing a double-layer halide perovskite film having excellent piezoelectric performance by using an eco-friendly solvent.

Another object of the present invention is to provide a double-layer halide perovskite film that is preparable by using an eco-friendly solvent and has excellent piezoelectric performance.

Still another object of the present invention is to provide an energy harvesting device having excellent performance by comprising the double-layer halide perovskite film.

### Means for Solving the Problem

To achieve the above object, the present invention provides a method for preparing a double-layer halide perovskite film, comprising steps of (i) respectively preparing a first precursor solution comprising a precursor material of a three-dimensional halide perovskite and a lactate ester solvent, and a second precursor solution comprising a zero-dimensional halide perovskite material and a monoterpene solvent; (ii) forming a three-dimensional halide perovskite layer by coating the first precursor solution on a substrate; and (iii) forming a zero-dimensional halide perovskite layer by coating the second precursor solution on the three-dimensional halide perovskite layer.

In the present invention, the three-dimensional halide perovskite may have a structure of ABX₃. At this time, A may be CH₃NH₃, (CH₃NH₃)₂, CF₃NH₃, formamidinium, acetamidinium, or guamidinium, B may be Pb, Sn, Cu, Mn, Ge, Ni, Co, Fe, Cr, Pd, Cd, or Yb, and X may be F, Cl, Br, or I.

In the present invention, the precursor material of the three-dimensional halide perovskite may comprise an AX powder and a BX₂ powder.

In the present invention, the lactate ester solvent may comprise at least one selected from the group consisting of ethyl lactate, methyl lactate, n-propyl lactate, isopropyl lactate, n-butyl lactate, isobutyl lactate, t-butyl lactate, pentyl lactate, and hexyl lactate.

In the first precursor solution, a total concentration of the precursor material may be 10 to 300 g/L.

In the present invention, the zero-dimensional halide perovskite may have a structure of A′BX₃. At this time, A′ may be Cs, Rb, or Fr, B may be Pb, Sn, Cu, Mn, Ge, Ni, Co, Fe, Cr, Pd, Cd, or Yb, and X may be F, Cl, Br, or I.

In the present invention, the monoterpene solvent may comprise at least one selected from the group consisting of limonene, myrcene, ocimene, terpinolene, and terpinene.

In the second precursor solution, a concentration of the zero-dimensional halide perovskite may be 50 to 500 g/L.

In the present invention, the second precursor solution may further comprise a polymer material.

The polymer material comprised in the second precursor solution may be at least one selected from the group consisting of poly(methyl methacrylate) (PMMA), poly(methyl acrylate) (PMA), polyurethane (PU), poly(vinyl acetate) (PVAc), polystyrene (PS), polyethylene oxide (PEO), polypropylene oxide (PPO), cellulose acetate, polycarbonate (PC), poly(vinyl chloride) (PVC), polycaprolactone (PCL), poly(vinyl carbazole) (PVK), poly(vinylidene fluoride) (PVdF), polyamide, and copolymers thereof.

In the present invention, the coatings of the steps (ii) and (iii) may be respectively performed by spin coating, spray coating, bar coating, dip coating, curtain coating, slot coating, roll coating, or gravure coating.

In the steps (ii) and (iii), after coating, each perovskite layer may be formed by heat-treating at a temperature of 100 to 150° C. for 1 to 30 minutes.

The present invention also provides a double-layer halide perovskite film prepared by the above method.

The double-layer halide perovskite film prepared according to the present invention comprises a three-dimensional halide perovskite layer and a zero-dimensional halide perovskite layer formed on the three-dimensional halide perovskite layer.

The present invention also provides an energy harvesting device comprising the double-layer halide perovskite film.

The energy harvesting device may have a structure comprising a substrate; a lower electrode layer located on the substrate; the double-layer halide perovskite film located on the lower electrode layer; and an upper electrode layer located on the double-layer halide perovskite film.

In the present invention, the energy harvesting device may be a piezoelectric device.

### Effects of the Invention

In the present invention, by using lactate ester and monoterpene, which are eco-friendly solvents, as solvents of the precursor solutions during the formation of the halide perovskite layers, the perovskite layers can be stably formed, and a perovskite film having excellent piezoelectric performance can be prepared according to the formation of a double-layer structure of a three-dimensional perovskite and a zero-dimensional perovskite. Therefore, by using the present invention, an environmental pollution problem caused by the use of a solvent during the formation of the perovskite film can be solved, and the piezoelectric performance of the film can be greatly improved through optimization of materials and structure.

### SIMPLE DESCRIPTION OF DRAWINGS

FIG. 1 schematically illustrates a structure of an energy harvesting device according to one embodiment of the present invention.

FIG. 2 schematically illustrates a method for preparing an MASnBr₃ precursor solution according to one embodiment of the present invention.

FIG. 3 schematically illustrates a method for preparing a CsPbBr₃ precursor solution according to one embodiment of the present invention.

FIG. 4 shows photographs before and after UV irradiation of the CsPbBr₃ precursor solution prepared in one embodiment of the present invention.

FIGS. 5A and 5B schematically illustrate a method for preparing a perovskite film having a double-layer structure of MASnBr₃/CsPbBr₃ according to one embodiment of the present invention.

FIG. 6 shows a luminescence image of the perovskite film prepared according to one embodiment of the present invention.

FIG. 7 shows a comparison of output voltages according to stacked structures of the piezoelectric device prepared according to one embodiment of the present invention.

FIG. 8 shows a comparison of output voltages according to solvents of the piezoelectric device prepared according to one embodiment of the present invention.

### MODES FOR CARRYING OUT THE INVENTION

Unless otherwise defined, all technical and scientific terms used in the present specification have the same meanings as commonly understood by experts skilled in the technical field to which the present invention pertains. In general, the nomenclature used in the present specification is well known and commonly used in the technical field.

In the present specification, when a component such as a substrate or a layer is said to be “on” another component, this may include not only a case where it is directly on the other component but also a case where another component is present therebetween.

The present invention relates to a perovskite film having a double-layer structure, which is prepared by using a halide perovskite material and an eco-friendly solvent.

In the present invention, by using lactate ester and monoterpene, which are eco-friendly solvents, as solvents of the halide perovskite precursor, the perovskite layers can be stably formed. In addition, according to the formation of a double-layer structure of a three-dimensional perovskite and a zero-dimensional perovskite, a perovskite film having very excellent piezoelectric performance can be prepared. Therefore, by using the present invention, an environmental pollution problem caused by the use of a solvent during the formation of the perovskite film can be solved, and depending on optimization of materials and structure, the perovskite film exhibits very excellent piezoelectric characteristics and can be usefully used as an active layer of a piezoelectric device.

Accordingly, the present invention provides a method for preparing a halide perovskite film having a double-layer structure by using an eco-friendly solvent.

The method of the present invention comprises steps of (i) preparing a first precursor solution comprising a precursor material of a three-dimensional halide perovskite and a lactate ester solvent, and a second precursor solution comprising a precursor material of a zero-dimensional halide perovskite and a monoterpene solvent; (ii) forming a three-dimensional halide perovskite layer by coating the first precursor solution on a substrate; and (iii) forming a zero-dimensional halide perovskite layer by coating the second precursor solution on the three-dimensional halide perovskite layer.

The perovskite refers to a material having a crystal structure formed by binding two types of cations and one type of anion, and the halide perovskite material usable in the present invention may be a perovskite in the form of quantum dots having a zero-dimensional nanostructure or a perovskite having a three-dimensional structure.

In general, when forming a halide perovskite thin film having a three-dimensional nanostructure, an aprotic solvent such as dimethylformamide (DMF) is used in terms of solubility of the precursor components. However, dimethylformamide had a problem in that it is harmful to the human body and is not eco-friendly because it has toxic components. In addition, as a solvent of the halide perovskite having a zero-dimensional nanostructure in the form of quantum dots, nonpolar hydrocarbon solvents such as toluene and chlorobenzene are used, and these also are known to have toxicity.

The present invention is intended to solve these problems, and, when preparing a precursor solution, a lactate ester compound is used as a solvent of a precursor material of a halide perovskite having a three-dimensional nanostructure, and a monoterpene compound is used as a solvent of a halide perovskite material having a zero-dimensional nanostructure. In the present invention, by using eco-friendly solvents as described above, a precursor solution having high solubility of perovskite can be prepared, and a perovskite film having piezoelectric performance can be stably formed using the precursor solution.

In the present invention, the perovskite having the three-dimensional structure may have a structure of ABX₃. In the above formula, A is a monovalent organic cation, B is a divalent metal cation, and X is a halogen element.

Specifically, A may be an ammonium ion such as CH₃NH₃, (CH₃NH₃)₂, or CF₃NH₃; or an amidinium-type ion such as formamidinium, acetamidinium, or guamidinium, B may be Pb, Sn, Cu, Mn, Ge, Ni, Co, Fe, Cr, Pd, Cd, or Yb, and X may be F, Cl, Br, or I.

The precursor material for forming the three-dimensional perovskite comprises an AX powder and a BX₂ powder, and the precursor material is dissolved in a lactate ester solvent to prepare a precursor solution. For example, when preparing a film comprising MASnBr₃, MABr and SnBr₂ may be used as the precursors.

In the present invention, the lactate ester used refers to a compound in which an ester bond is formed between a carboxyl group of lactic acid and a hydrocarbon group. For example, as the lactate ester compound, at least one selected from the group consisting of ethyl lactate, methyl lactate, n-propyl lactate, isopropyl lactate, n-butyl lactate, isobutyl lactate, t-butyl lactate, pentyl lactate, and hexyl lactate may be used.

Preferably, ethyl lactate may be used as the lactate ester solvent. In the case of ethyl lactate, the precursor material of the three-dimensional perovskite can be dissolved very effectively, and a thin film having piezoelectric performance can be stably formed by using the same. In this regard, in the example of the present invention, it was confirmed that when an MASnBr₃ powder was dissolved in ethyl lactate to form a precursor solution and the solution was coated, a perovskite thin film was stably formed and exhibited piezoelectric performance.

In the first precursor solution, a concentration of the precursor may be 10 to 300 g/L. Specifically, concentrations of AX and BX₂ may be 5 to 100 g/L and 10 to 200 g/L, respectively, and preferably, the concentration of the AX may be 10 to 50 g/L, and the concentration of the BX₂ may be 20 to 80 g/L. In the above range, the perovskite thin film is stably formed by the precursor material and exhibits sufficient piezoelectric performance, and thus is preferable.

The first precursor solution may be prepared by adding the precursor to the solvent and stirring at a temperature of room temperature to 90° C., preferably 50 to 70° C., for 10 minutes to 3 hours, preferably 30 minutes to 2 hours.

In the present invention, the perovskite having the zero-dimensional structure may have a structure of A′BX₃. In the above formula, A′ is an alkali metal cation, B is a divalent metal cation, and X is a halogen element.

Specifically, A′ may be Cs, Rb, or Fr, B may be Pb, Sn, Cu, Mn, Ge, Ni, Co, Fe, Cr, Pd, Cd, or Yb, and X may be F, Cl, Br, or I.

To form the zero-dimensional perovskite, a precursor solution is prepared by dispersing an A′BX₃ material in the form of quantum dots in a monoterpene compound solvent.

In the present invention, the monoterpene compound used refers to isomers having a chemical formula of C₁₀H₁₆, which are terpene compounds composed of two isoprene units. For example, the monoterpene compound may comprise at least one selected from the group consisting of limonene, myrcene, ocimene, terpinolene, and terpinene.

Preferably, the monoterpene compound may be limonene. When limonene is used, a perovskite material having a zero-dimensional structure is very effectively dispersed, and a thin film having piezoelectric performance can be stably formed. In this regard, in the example of the present invention, it was confirmed that when a precursor solution was formed by dispersing a CsPbBr₃ quantum dot powder in limonene and coating the same to form a thin film, a perovskite thin film exhibiting piezoelectric performance was stably formed.

In the second precursor solution, a concentration of the zero-dimensional perovskite material may be 50 to 500 g/L, preferably 80 to 200 g/L. By using a solution within the above concentration range, a zero-dimensional perovskite thin film exhibiting piezoelectric performance can be stably formed.

The second precursor solution may be prepared by dispersing the zero-dimensional perovskite powder in the solvent, and may be dispersed after being added at a temperature of room temperature to 90° C., preferably 50 to 70° C.

In a preferred embodiment of the present invention, the second precursor solution may further comprise a polymer material.

In the second precursor solution, the polymer material may be added to serve as a matrix for improving the dispersibility of the zero-dimensional perovskite material in the form of quantum dots.

For example, the polymer material may be at least one selected from the group consisting of poly(methyl methacrylate) (PMMA), poly(methyl acrylate) (PMA), polyurethane (PU), poly(vinyl acetate) (PVAc), polystyrene (PS), polyethylene oxide (PEO), polypropylene oxide (PPO), cellulose acetate, polycarbonate (PC), poly(vinyl chloride) (PVC), polycaprolactone (PCL), poly(vinyl carbazole) (PVK), poly(vinylidene fluoride) (PVdF), polyamide, and copolymers thereof.

Particularly, when poly(methyl methacrylate) (PMMA) is used as the polymer material of the second precursor solution, it exhibits excellent solubility in the monoterpene compound which is the solvent of the second precursor solution. Therefore, by the addition of PMMA, the zero-dimensional perovskite material can be more uniformly dispersed in the second precursor solution, and thus is preferable.

In the present invention, the polymer material may be comprised in the second precursor solution at a concentration of 5 to 50 g/L, preferably 10 to 20 g/L. By this, a matrix capable of uniformly dispersing the zero-dimensional perovskite material can be formed.

In the above embodiment, the second precursor solution may be prepared by adding the polymer material to the solvent and stirring at a temperature of room temperature to 90° C., preferably 50 to 70° C., for 10 minutes to 3 hours, preferably 30 minutes to 2 hours, and then mixing with the zero-dimensional perovskite material.

The method of the present invention may further comprise a step of adding nano-particles having piezoelectric properties, the nano-particles being at least one selected from the group consisting of ZnO, ZnSnO₃, GaN, Te, CdTe, CdSe, KNbO₃, NaNbO₃, InN, AlPO₄, GaPO₄, La₃Ga₅SiO₁₄, BaTiO₃, Bi₄Ti₃O₁₂, PbTiO₃, ZnO, PZT (lead zirconate titanate), BLT (bismuth lanthanum titanate), SnO₂, KNbO₃, LiNbO₃, LiTaO₃, Na₂WO₃, Ba₂NaNb₅O₅, Pb₂KNb₅O₁₅, KNaNb₅O₅, and BiFeO₃, to each precursor solution.

In addition, the method may further comprise a step of adding quantum dot powders having luminescent properties, such as GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, InAlPAs, to each precursor solution so that the prepared film exhibits color-conversion properties.

In addition, the method may further comprise a step of adding energy conversion materials such as graphite, carbon black, carbon nanotube (CNT), carbon nanofiber (CNF), graphene, and boron nitride nanotube (BNNT) to each precursor solution so that the prepared composite film has two or more energy conversion properties or so that the energy conversion performance is further improved.

In addition, the method may further comprise a step of adding P(VDF(vinylidene fluoride)-TrFE(trifluoroethylene)-CTFE(chloro trifluoroethylene)) or P(VDF(vinylidene fluoride)-TrFE(trifluoroethylene)-CFE(chloro fluoro ethylene)) to each precursor solution. By this, the energy conversion performance can be further improved.

When the precursor solution is prepared, it is coated on a substrate to form a perovskite film.

Specifically, a double-layer structured perovskite film can be prepared by forming a three-dimensional halide perovskite layer by coating the first precursor solution on the substrate, and then forming a zero-dimensional halide perovskite layer by coating the second precursor solution on the three-dimensional halide perovskite layer.

The substrate is for forming a film, and its type is not particularly limited, and a substrate commonly used in electronic devices may be appropriately selected and used. For example, the substrate may be at least one base substrate selected from the group consisting of glass, PEN (polyethylene naphthalate), PET (polyethylene terephthalate), PS (polystyrene), PC (polycarbonate), PI (polyimide), PVC (polyvinyl chloride), PVP (polyvinylpyrrolidone), PE (polyethylene), stainless steel, wool fabric, silicon (Si), and SiO2, or may be one in which an electrode is formed on the base substrate.

In the present invention, coating of each precursor solution may be performed by using coating technologies such as spin coating, spray coating, bar coating, dip coating, curtain coating, slot coating, roll coating, or gravure coating.

After coating the precursor solution of the perovskite as described above, when the residual solvent is removed through drying and heat treatment, a perovskite layer is formed. At this time, the heat treatment may be performed at a temperature of 100 to 150° C. for 1 to 30 minutes.

By using the perovskite layer-forming process as described above, a double-layer structured film is formed by sequentially forming a three-dimensional perovskite layer and a zero-dimensional perovskite layer using the first precursor solution and the second precursor solution. In the present invention, by forming a double-layer structured perovskite film using eco-friendly solvents as described above, a film having very excellent piezoelectric performance can be prepared by a method that is not harmful to the human body and the environment.

In this regard, in the example of the present invention, when applied to a piezoelectric device, a perovskite film having a single-layer or double-layer structure formed of MASnBr₃, which is a three-dimensional perovskite material, and CsPbBr₃, which is a zero-dimensional perovskite material, using eco-friendly solvents, it was confirmed that the three-dimensional/zero-dimensional double-layer structured perovskite film exhibited very excellent output voltage compared to the three-dimensional perovskite single-layer and the zero-dimensional perovskite single-layer.

In the present invention, by using lactate ester and monoterpene, which are eco-friendly solvents, as solvents of the halide perovskite precursor, the perovskite layers can be stably formed, and a perovskite film having very excellent piezoelectric performance can be prepared according to the formation of a double-layer structure of a three-dimensional perovskite and a zero-dimensional perovskite. Therefore, by using the present invention, an environmental pollution problem caused by the use of a solvent during the formation of the perovskite film can be solved, and the piezoelectric performance of the film can be greatly improved through optimization of materials and structure, and thus is preferable.

The present invention also relates to an energy harvesting device comprising the perovskite film.

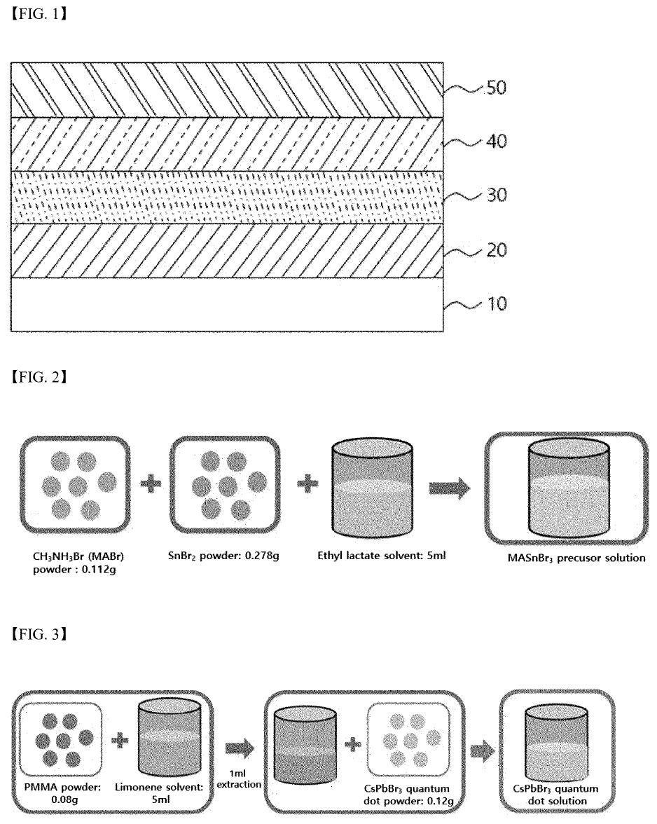

FIG. 1 shows a conceptual diagram of an energy harvesting device according to one embodiment of the present invention.

Referring to FIG. 1, the energy harvesting device of the present invention comprises a substrate (10), a lower electrode layer (20) located on the substrate, a three-dimensional perovskite layer (30) located on the lower electrode layer and comprising a three-dimensional perovskite material, a zero-dimensional perovskite layer (40) located on the three-dimensional perovskite layer, and an upper electrode layer (50) located on the zero-dimensional perovskite layer.

The substrate may be used without limitation as long as it is a substrate capable of serving as a support of the device. For example, the substrate may be at least one substrate selected from the group consisting of glass, PEN (polyethylene naphthalate), PET (polyethylene terephthalate), PS (polystyrene), PC (polycarbonate), PI (polyimide), PVC (polyvinyl chloride), PVP (polyvinylpyrrolidone), PE (polyethylene), stainless steel, wool fabric, silicon (Si), and SiO₂.

The lower electrode layer may comprise at least one conductive material selected from the group consisting of Al, Ag, Au, Ti, Ni, Mo, Cu, Pt, Fe or alloys thereof, TiN, WN, SrTiO₃, LaNiO₃, ITO (indium tin oxide), IZO (indium zinc oxide), GZO (gallium zinc oxide), IGZO (indium gallium-doped zinc oxide), AZO (aluminum zinc oxide), ZnO, SnO₂, TiO₂, nanowire, carbon nanotube (CNT), SWCNT (single-walled carbon nanotube), DWCNT (double-walled carbon nanotube), MWCNT (multi-walled carbon nanotube), graphene, PEDOT (polyethylenedioxythiophene), and PEDOT:PSS (poly(3,4-ethylenedioxythiophene):polystyrenesulfonate).

The upper electrode layer may be the same as or different from the lower electrode layer, and the conductive material constituting the upper electrode layer is the same as described for the lower electrode layer, and therefore omitted.

In the energy harvesting device of the present invention, the perovskite film having the three-dimensional/zero-dimensional double-layer structure according to the present invention may be used as an active layer.

In the present invention, the energy harvesting device may further comprise at least one layer selected from the group consisting of a hole injection layer, an electron injection layer, an electron transport layer, and an energy conversion layer on an upper surface, a lower surface, or an upper/lower surface of the active layer.

The energy harvesting device according to the present invention may be a piezoelectric, photovoltaic, thermoelectric, or triboelectric device, or a hybrid device thereof. Preferably, the energy harvesting device of the present invention may be a piezoelectric device that harvests electrical energy from pressure or vibration. When applying the three-dimensional/zero-dimensional double-layer structured perovskite film prepared using an eco-friendly solvent according to the present invention to a piezoelectric device, it can exhibit very excellent piezoelectric output compared to a perovskite film prepared using a conventional non-eco-friendly solvent and a single-layer perovskite film.

In the present invention, the energy harvesting device can be applied to a piezoelectric resonator, a piezoelectric speaker, a piezoelectric actuator, and a piezoelectric transducer, and can also be used in a photodetector, a gas sensor, a biosensor, a position sensor, a touch sensor, a lithium-ion battery, a resistive memory, a transistor-type memory, a memristor, and a ferroelectric memory.

### EXAMPLES

Hereinafter, the present invention will be described in more detail through Examples. However, these Examples show some experimental methods and compositions in order to illustratively describe the present invention, and the scope of the present invention is not limited to these Examples.

### Preparation Example 1: Preparation of a Perovskite Film having a Three-Dimensional/Zero-dimensional Double-layer Structure

A perovskite precursor solution was respectively prepared by using eco-friendly solvents, and these were sequentially coated to prepare a perovskite film having a double-layer structure.

As shown in FIGS. 2, 0.112 g of methylammonium bromide (MABr) powder and 0.278 g of SnBr₂ powder were added to 5 mL of an ethyl lactate solvent and stirred at 60° C. for 1 hour to prepare an MASnBr₃ precursor solution.

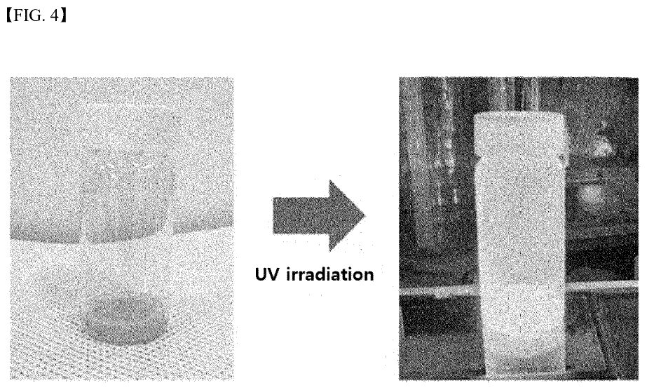

In addition, as shown in FIGS. 3, 0.08 g of poly(methyl methacrylate) (PMMA) powder was mixed with 5 mL of a limonene solvent and stirred at 60° C. for 1 hour, and then 1 mL thereof was extracted and mixed with 0.12 g of CsPbBr₃ quantum dots to prepare a CsPbBr₃ quantum dot dispersion. FIG. 4 shows photographs before and after UV light irradiation of the quantum dot dispersion, and it was confirmed from the result of green light emission upon UV light irradiation that the CsPbBr₃ quantum dots were not decomposed and were stably dispersed in limonene.

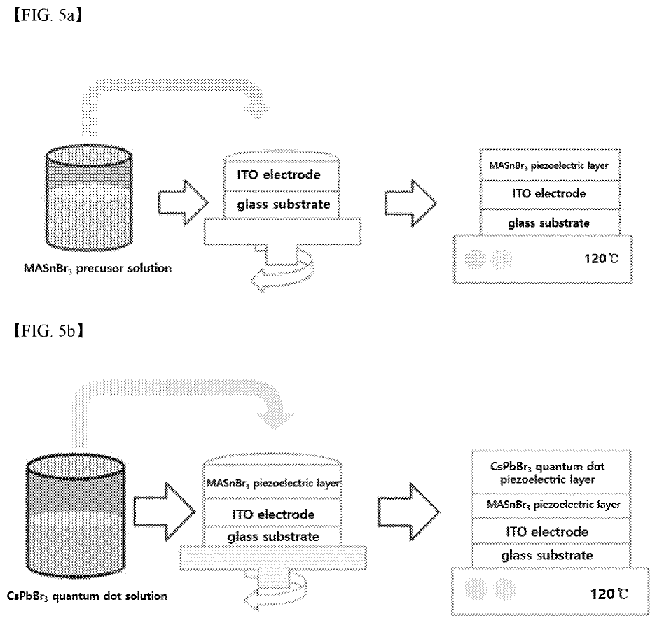

Next, as shown in FIG. 5A, after dropping the MASnBr₃ precursor aqueous solution onto an ITO electrode substrate, spin coating was performed at 1,000 rpm/30 seconds, followed by annealing at 120° C. for 10 minutes to form an MASnBr₃ piezoelectric thin film. Thereafter, as shown in FIG. 5B, after dropping the CsPbBr₃ quantum dot dispersion on the formed MASnBr₃ thin film, spin coating was performed at 1,000 rpm/30 seconds, followed by annealing at 120° C. for 10 minutes to form a CsPbBr₃ quantum dot thin film. Thus, a piezoelectric thin film having an MASnBr₃/CsPbBr₃ double-layer structure was prepared.

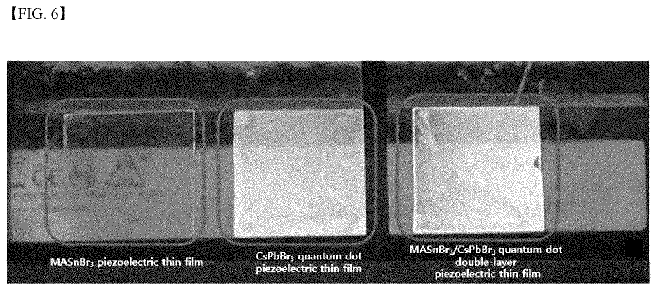

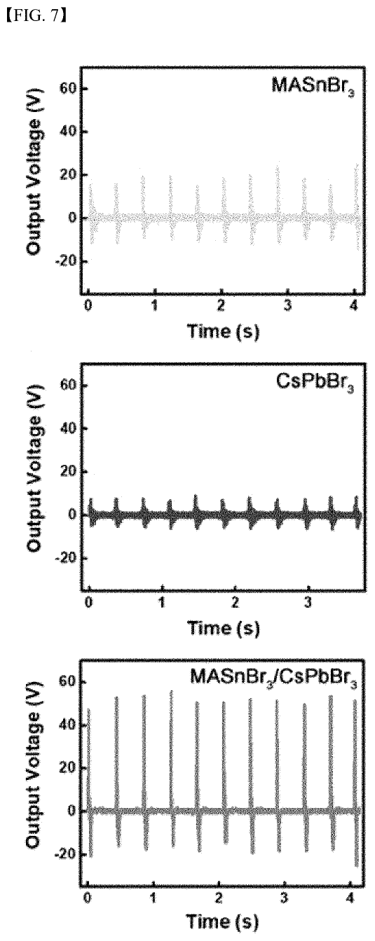

FIG. 6 shows UV irradiation images of the MASnBr₃/CsPbBr₃ double-layer thin film, the MASnBr₃ single-layer thin film, and the CsPbBr₃ single-layer thin film, and it can be confirmed that green luminescence appears in the CsPbBr₃ thin film and the MASnBr₃/CsPbBr₃ thin film. Accordingly, it was found that the CsPbBr₃ quantum dot thin film was successfully formed on the MASnBr₃ thin film.

### Preparation Example 2: Preparation of Piezoelectric Device using Perovskite Film

The first precursor solution was prepared by the method of Preparation Example 1, and was applied onto an ITO-coated glass substrate to form a three-dimensional perovskite layer. Thereafter, by coating the second precursor solution according to the method of Preparation Example 1 to form a zero-dimensional perovskite layer, a perovskite film having a double-layer structure was formed as an active layer of a piezoelectric device. Next, a piezoelectric device was prepared by attaching a copper electrode tape (Cu electrode tape) on the perovskite film.

### Experimental Example 2: Comparative Analysis of Performance of Piezoelectric Devices According to Perovskite Film Structure

The output voltage of a device having an MASnBr₃/CsPbBr₃ perovskite film prepared in Preparation Example 2 was measured. For comparison, the output voltages were also measured for a device having an MASnBr₃ single layer and a device having a CsPbBr₃ single layer as a piezoelectric active layer.

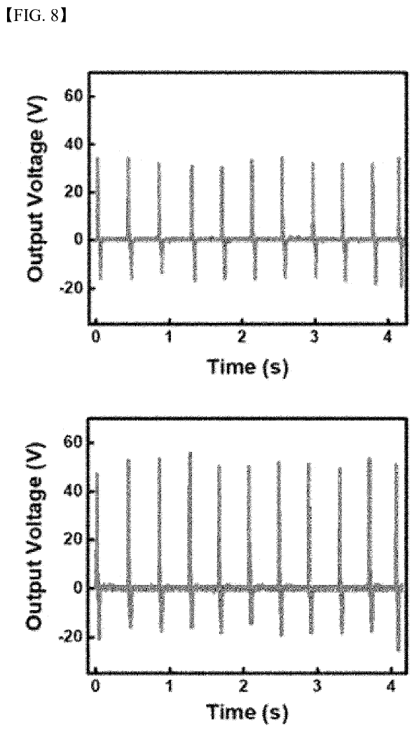

Specifically, after connecting copper wires to both electrodes of the device and connecting a probe of an oscilloscope to the copper wires, piezoelectric output was measured while applying a force of 10 KPa to the upper portion of the device at a frequency of about 4 Hz, and the results are shown in FIG. 7.

Referring to FIG. 7, it can be confirmed that the output voltage of the device having an MASnBr₃/CsPbBr₃ double-layer film is very high compared to the piezoelectric device having an MASnBr₃ single layer or a CsPbBr₃ single layer. Specifically, while the average output voltage of the MASnBr₃ single-layer piezoelectric device was 18.7 V and that of the CsPbBr₃ single-layer piezoelectric device was 7.65 V, the average output voltage of the MASnBr₃/CsPbBr₃ double-layer piezoelectric device was 52 V, and it was confirmed that the double-layer piezoelectric device of the present invention exhibited more than two times the output compared to the sum of the outputs of the respective single-layer devices.

According to the above experimental results, it was confirmed that a piezoelectric device having a very excellent piezoelectric response characteristic can be prepared according to the formation of a double-layer structure using eco-friendly solvents.

### Experimental Example 3: Comparative Analysis of Performance of Piezoelectric Devices According to Types of Solvents

The output voltage of a device having an MASnBr₃/CsPbBr₃ perovskite film prepared in Preparation Example 2 was measured. For comparison, the output voltage was also measured for a piezoelectric device prepared using a dimethylformamide (DMF) solvent instead of ethyl lactate and a toluene solvent instead of limonene.

FIG. 8 shows a comparison of the output voltage graphs of a piezoelectric device prepared using the non-eco-friendly solvents (upper) and the piezoelectric device of Preparation Example 2 (lower). According to the above experimental results, when ethyl lactate and limonene were used as eco-friendly solvents according to the present invention, it was confirmed that the performance of the piezoelectric device was rather superior compared to the case of using the conventional non-eco-friendly solvents DMF and toluene. Specifically, while the average output voltage of the piezoelectric device of the present invention was 52 V, the average output of the piezoelectric device prepared using non-eco-friendly solvents was 32.8 V, and the output voltage of the piezoelectric device was improved by more than 50% when applying the solvent of the present invention.

Accordingly, in the present invention, it was found that by using ethyl lactate and limonene as eco-friendly solvents, a piezoelectric device having superior performance compared to the conventional non-eco-friendly solvents could be manufactured.

As described above, specific parts of the contents of the present invention have been described in detail, and it is obvious that such detailed description is merely a preferred embodiment for those of ordinary skill in the art, and the scope of the present invention is not limited thereby. Therefore, the substantial scope of the present invention will be defined by the appended claims and their equivalents.

What is claimed is:

1. A method for preparing a double-layer halide perovskite film, comprising steps of:
(i) respectively preparing a first precursor solution comprising a precursor material of a three-dimensional halide perovskite and a lactate ester solvent, and a second precursor solution comprising a zero-dimensional halide perovskite material and a monoterpene solvent;
(ii) forming a three-dimensional halide perovskite layer by coating the first precursor solution on a substrate; and
(iii) forming a zero-dimensional halide perovskite layer by coating the second precursor solution on the three-dimensional halide perovskite layer.

2. The method for preparing a double-layer halide perovskite film according to claim 1,
wherein the three-dimensional halide perovskite has a structure of ABX₃,
wherein A is CH₃NH₃, (CH₃NH₃)₂, CF₃NH₃, formamidinium, acetamidinium or guamidinium,
wherein B is Pb, Sn, Cu, Mn, Ge, Ni, Co, Fe, Cr, Pd, Cd or Yb, and
wherein X is F, Cl, Br or I.

3. The method for preparing a double-layer halide perovskite film according to claim 2,
wherein the precursor material of the three-dimensional halide perovskite comprises an AX powder and a BX₂ powder.

4. The method for preparing a double-layer halide perovskite film according to claim 1,
wherein the lactate ester solvent comprises at least one selected from the group consisting of ethyl lactate, methyl lactate, n-propyl lactate, isopropyl lactate, n-butyl lactate, isobutyl lactate, t-butyl lactate, pentyl lactate and hexyl lactate.

5. The method for preparing a double-layer halide perovskite film according to claim 1,
wherein, in the first precursor solution, a total concentration of the precursor material is 10 to 300 g/L.

6. The method for preparing a double-layer halide perovskite film according to claim 1,
wherein the zero-dimensional halide perovskite has a structure of A′BX₃,
wherein A′ is Cs, Rb or Fr,
wherein B is Pb, Sn, Cu, Mn, Ge, Ni, Co, Fe, Cr, Pd, Cd or Yb, and
wherein X is F, Cl, Br or I.

7. The method for preparing a double-layer halide perovskite film according to claim 1,
wherein the monoterpene solvent comprises at least one selected from the group consisting of limonene, myrcene, ocimene, terpinolene and terpinene.

8. The method for preparing a double-layer halide perovskite film according to claim 1,
wherein, in the second precursor solution, a concentration of the zero-dimensional halide perovskite is 50 to 500 g/L.

9. The method for preparing a double-layer halide perovskite film according to claim 1,
wherein the second precursor solution further comprises a polymer material.

10. The method for preparing a double-layer halide perovskite film according to claim 9,
wherein the polymer material is at least one selected from the group consisting of poly(methyl methacrylate) (PMMA), poly(methyl acrylate) (PMA), polyurethane (PU), poly(vinyl acetate) (PVAc), polystyrene (PS), polyethylene oxide (PEO), polypropylene oxide (PPO), cellulose acetate, polycarbonate (PC), poly(vinyl chloride) (PVC), polycaprolactone (PCL), poly(vinyl carbazole) (PVK), poly(vinylidene fluoride) (PVdF), polyamide and copolymers thereof.

11. The method for preparing a double-layer halide perovskite film according to claim 1,
wherein the coatings of the steps (ii) and (iii) are respectively performed by spin coating, spray coating, bar coating, dip coating, curtain coating, slot coating, roll coating or gravure coating.

12. The method for preparing a double-layer halide perovskite film according to claim 1,
wherein, in the steps (ii) and (iii), after coating, a perovskite layer is formed by heat-treating at a temperature of 100 to 150° C. for 1 to 30 minutes.

13. A double-layer halide perovskite film prepared by the method according to claim 1, comprising
a three-dimensional halide perovskite layer, and
a zero-dimensional halide perovskite layer formed on the three-dimensional halide perovskite layer.

14. An energy harvesting device comprising:
a substrate;
a lower electrode layer located on the substrate;
the double-layer halide perovskite film according to claim 13, located on the lower electrode layer; and
an upper electrode layer located on the double-layer halide perovskite film.

15. The energy harvesting device according to claim 14,
wherein the energy harvesting device is a piezoelectric device.
